(19) United States
(12) Patent Application Publication
(10) Pub. No.: US 2026/0314227 A1
(43) Pub. Date: Oct. 8, 2026

(54) DISPLAY DEVICE AND ELECTRONIC DEVICE

(71) Applicant: Samsung Display Co., Ltd., Yongin-si (KR)

(72) Inventors: Yong Seok KIM, Yongin-si (KR); Soo Bin KIM, Yongin-si (KR); Ji Young NAM, Yongin-si (KR); Dong Chul SHIN, Yongin-si (KR); Hae Ju YUN, Yongin-si (KR); Jong Cheon LEE, Yongin-si (KR)

(21) Appl. No.: 19/353,726

(22) Filed: Oct. 9, 2025

(30) Foreign Application Priority Data
Apr. 3, 2025 (KR) 10-2025-0043682

(51) Int. Cl. H10K 59/50; H10K 59/38; H10K 59/40; H10K 59/80

(52) U.S. Cl. CPC H10K 59/50; H10K 59/38; H10K 59/40; H10K 59/8792

(57) ABSTRACT

A display device includes: a first circuit layer; a display element layer on the first circuit layer; an electrochromic element on the display element layer; a second circuit layer electrically connected to the electrochromic element; and a color filter layer on the electrochromic element, wherein the display element layer comprises a first light emitting element and a second light emitting element, wherein the electrochromic element comprises a first electrochromic element overlapping with the first light emitting element and a second electrochromic element overlapping with the second light emitting element, and wherein the first electrochromic element and the second electrochromic element are configured to be driven individually.

### CROSS-REFERENCE TO RELATED APPLICATION

The present application claims priority to and the benefit of Korean Patent Application Number 10-2025-0043682, filed on Apr. 3, 2025, in the Korean Intellectual Property Office, the entire disclosure of which is incorporated herein by reference.

### BACKGROUND

### 1. Field

Aspects of some embodiments of the present disclosure relate to a display device and an electronic device.

### 2. Description of the Related Art

As information technology has developed, importance of a display device, which is a connection medium between a user and information, has been highlighted. Accordingly, research and development on a display device are continuously being conducted.

The display device may include an organic light emitting diode (OLED). OLED display devices have superior viewing angles, contrast ratios, and the like compared to liquid crystal display devices. However, in a typical OLED display, increased reflectance due to the OLEDs and electrodes may result in frequent occurrences of external light reflection.

The above information disclosed in this Background section is only for enhancement of understanding of the background and therefore the information discussed in this Background section does not necessarily constitute prior art.

### SUMMARY

Aspects of some embodiments of the present disclosure include a display device capable of switching from a self-emissive display device to a reflective display device or from a reflective display device to a self-emissive display device.

Aspects of some embodiments of the present disclosure include an electronic device including the display device.

The characteristics of embodiments according to the present disclosure are not limited to the characteristics as mentioned above, and other characteristics that are not mentioned will be more apparent to those skilled in the art from the following descriptions.

A display device according to one or more embodiments of the present disclosure includes: a first circuit layer; a display element layer on the first circuit layer; an electrochromic element on the display element layer; a second circuit layer electrically connected to the electrochromic element; and a color filter layer arranged over the electrochromic element, wherein the display element layer includes a first light emitting element and a second light emitting element, wherein the electrochromic element includes a first electrochromic element overlapping with the first light emitting element and a second electrochromic element overlapping with the second light emitting element, and wherein the first electrochromic element and the second electrochromic element are configured to be driven individually.

According to some embodiments, the second circuit layer may be arranged on the color filter layer.

According to some embodiments, the display device may further include a protective layer on the color filter layer, and the second circuit layer may be arranged between the color filter layer and the electrochromic element.

According to some embodiments, the protective layer may be an overcoat layer or a film layer.

According to some embodiments, the second circuit layer may be arranged between the display element layer and the electrochromic element.

According to some embodiments, the display device may further include a touch sensor layer on the color filter layer.

According to some embodiments, the display device may further include an adhesive layer arranged between the display element layer and the electrochromic element.

According to some embodiments, the display device may further include a filling layer arranged between the display element layer and the second circuit layer.

According to some embodiments, the filling layer may be composed of a vacuum or may include a filler.

According to some embodiments, the display device may further include: an encapsulation layer on the display element layer; and a touch sensor layer arranged between the encapsulation layer and the electrochromic element.

According to some embodiments, the color filter layer may include: a first color filter; a second color filter; and a black matrix arranged between the first color filter and the second color filter.

According to some embodiments, the electrochromic element may include: a first electrochromic element electrode; an electrochromic layer on the first electrochromic element electrode; and a second electrochromic element electrode on the electrochromic layer, and the black matrix may be spaced apart from the first electrochromic element electrode.

According to some embodiments, the electrochromic element may include: a first electrochromic element electrode; an electrochromic layer on the first electrochromic element electrode; and a second electrochromic element electrode on the electrochromic layer. According to some embodiments, the display device may further include a transparent inorganic layer arranged between the second electrochromic element electrode and the color filter layer.

According to some embodiments, the color filter layer may include: a first color filter; a second color filter; and a third color filter. In a portion of the display device, the first color filter, the second color filter, and the third color filter may overlap with each other.

According to some embodiments, the display device may further include a display area and a non-display area, and the electrochromic element may be electrically connected to the first circuit layer via a contact hole arranged in the non-display area.

An electronic device according to one or more embodiments of the present disclosure includes a display device and a processor. According to some embodiments, the display device includes: a first circuit layer; a display element layer on the first circuit layer; an electrochromic element on the display element layer; a second circuit layer electrically connected to the electrochromic element, and including a first electrochromic element circuit and a second electrochromic element circuit; and a color filter layer arranged on the electrochromic element. According to some embodiments, the electrochromic element includes a first electrochromic element and a second electrochromic element. According to some embodiments, the first electrochromic element is electrically connected to the first electrochromic element circuit. According to some embodiments, the second electrochromic element is electrically connected to the second electrochromic element circuit.

According to some embodiments, the second circuit layer may be arranged on the color filter layer.

According to some embodiments, the display device may further include a protective layer on the color filter layer, the second circuit layer may be arranged between the color filter layer and the electrochromic element, and the protective layer may be an overcoat layer or a film layer.

According to some embodiments, the display device may further include: a touch sensor layer on the color filter layer; and an adhesive layer arranged between the display element layer and the electrochromic element, and the second circuit layer may be arranged between the display element layer and the electrochromic element.

According to some embodiments, the display device may further include: a touch sensor layer on the color filter layer; and a filling layer arranged between the display element layer and the second circuit layer, and the second circuit layer may be arranged between the display element layer and the electrochromic element.

### BRIEF DESCRIPTION OF THE DRAWINGS

FIG. 1 is a schematic plan view of a display device according to some embodiments.

FIGS. 2 to 4 are schematic plan views illustrating aspects of a pixel of FIG. 1 according to some embodiments.

FIGS. 5 to 8 are schematic cross-sectional views of a display panel of FIG. 1 according to some embodiments.

FIG. 9 is a schematic diagram of aspects of an equivalent circuit of a sub-pixel included in a pixel of FIGS. 2 to 4.

FIG. 10 is a schematic cross-sectional view illustrating aspects of a light emitting element of FIG. 9.

FIG. 11 is a schematic cross-sectional view illustrating aspects of the light emitting element of FIG. 9.

FIGS. 12 to 15 are schematic cross-sectional views of a pixel according to some embodiments.

FIG. 16 is a block diagram of an electronic device according to some embodiments.

FIG. 17 includes schematic diagrams of an electronic device according to some embodiments.

### DETAILED DESCRIPTION

Various modifications and changes may be applied to the described embodiments in accordance with the disclosed concepts. It is further noted that the described embodiments may be illustrated in simplified drawings. However, the embodiments according to the concepts of the present disclosure are not construed as limited to the specified disclosures, and may include all changes, equivalents, or substitutes that do not depart from the spirit and technical scope of the present disclosure.

While terms such as “first” and “second” may be used to describe various components, such components should not be understood as being limited to the above terms. The above terminologies are used to distinguish one component from the other component, for example, a first component may be referred to as a second component without departing from the scope in accordance with the concept of the present disclosure and similarly, a second component may be referred to as a first component. As used in the description of embodiments and the appended claims, singular forms in the present disclosure are intended to include plural forms as well, unless the context clearly indicates otherwise.

In the present disclosure, it should be understood that terms “include” or “have” indicate that a feature, a number, a step, an operation, a component, a part or the combination those of described in the specification is present, but do not exclude a possibility of presence or addition of one or more other features, numbers, steps, operations, components, parts or combinations thereof, in advance. Further, when a layer, film, region, plate, or the like is described as being “on” another part, this includes not only a case where it is directly on another part, but also a case where one or more additional parts are interposed between the two. Furthermore, in the present specification, when a certain layer, film, region, plate, or the like is described as being formed “on” another part, the term “on” is not limited to a case where the part is formed directly on an upper surface, but also includes cases where it is formed on a side or lower surface of another part. Conversely, when a layer, film, region, plate, or the like is described as being “under” another part, this includes not only a case where it is “directly under” another part, but also a case where one or more additional parts are interposed between the two.

Aspects of some embodiments of the present disclosure relate to a display device and an electronic device. Hereinafter, a display device and an electronic device according to some embodiments of the present disclosure will be described with reference to the accompanying drawings.

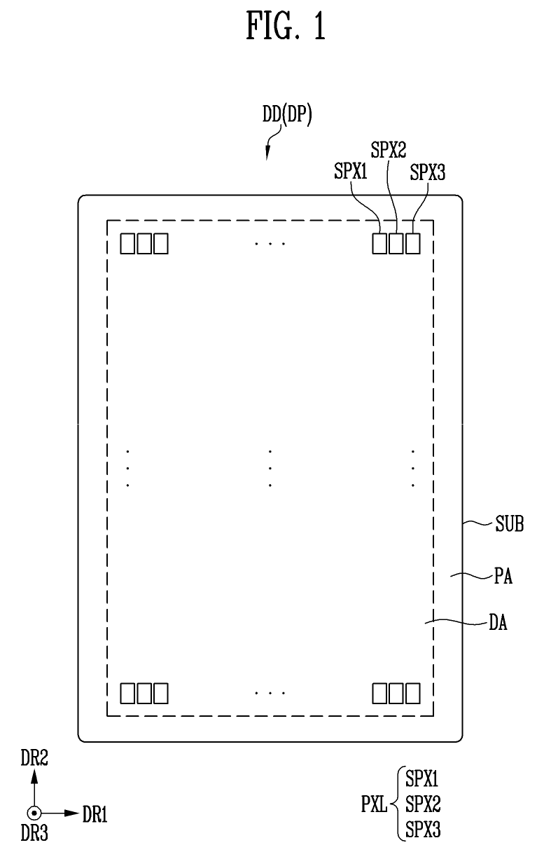

FIG. 1 is a schematic plan view of a display device DD according to some embodiments of the present disclosure.

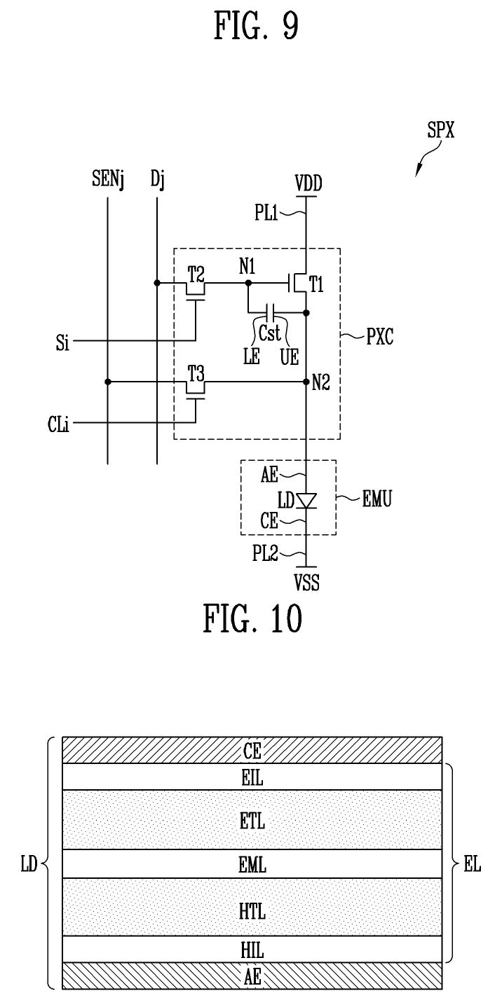

Referring to FIG. 1, a display panel DP (or display device DD) may display an image. The display panel DP may include a light emitting element LD (see FIG. 9). As the display panel DP, a self-emissive display panel may be used, such as an OLED panel or organic light emitting display panel utilizing organic light emitting diodes as light emitting elements.

The display panel DP may include a substrate SUB, and pixels PXL provided on the substrate SUB.

The substrate SUB may include a transparent insulating material, which allows light to pass through. The substrate SUB may be a rigid substrate or a flexible substrate. The rigid substrate may be one of, for example, a glass substrate, a quartz substrate, a glass-ceramic substrate, or a crystalline glass substrate.

The flexible substrate may be one of a film substrate and a plastic substrate, including a polymeric organic material. For example, the flexible substrate may include one or polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate.

The display device DD (or display panel DP) may have a variety of shapes. For example, according to some embodiments, the display device DD may be provided in a rectangular shape (e.g., with rounded or square corners), but embodiments according to the present disclosure are not limited thereto. For example, the display device DD may have a circular shape, oval shape, or irregular shape. Further, the display device DD may include angled and/or curved edges. For convenience, in FIG. 1, the display device DD is shown as having a rectangular plate shape. Further, in FIG. 1, an extension direction of the short side (e.g., a horizontal direction) (or a horizontal direction in a “row” direction of the pixels PXL) of the display device DD is indicated as a first direction DR1, and an extension direction of the long side (e.g., a vertical direction) (or a “column” direction of the pixels PXL) is indicated as a second direction DR2. Then, the display direction of the display device DD or the normal direction of the plane on which the substrate SUB is placed is indicated as a third direction DR3.

The substrate SUB (and display device DD) may include a display area DA for displaying images, and a peripheral area PA (or non-display area) surrounding (or excluding) (e.g., in a periphery or outside a footprint of) the display area DA. The substrate SUB may include the display area DA including pixel areas where the pixels PXL are arranged, respectively, and the peripheral area PA arranged around (or adjacent to) the display area DA.

The peripheral area PA may be located adjacent to (e.g., in a periphery or outside a footprint of) the display area DA. The peripheral area PA may be provided on at least one side of the display area DA. In one example, the peripheral area PA may surround the perimeter (or edge) of the display area DA. According to some embodiments, the peripheral area PA may be a bezel area of the display device DD.

In the display area DA on the substrate SUB, the pixels PXL may be arranged. The peripheral area PA may be arranged around the display area DA. The peripheral area PA may have a structure for protecting the configuration included in the pixels PXL arranged in the display area DA, but embodiments according to the present disclosure are not limited thereto. For example, the peripheral area PA may be provided with a line portion connected to each pixel PXL and a driver connected to the line portion and for driving the pixel PXL.

The pixel PXL may include a plurality of sub-pixels SPX1, SPX2, and SPX3. In one example, the pixel PXL may include a first sub-pixel SPX1, a second sub-pixel SPX2, and a third sub-pixel SPX3. The first sub-pixel SPX1, the second sub-pixel SPX2, and the third sub-pixel SPX3 may be sequentially arranged in the first direction DR1, but are not limited thereto, and the first sub-pixel SPX1, the second sub-pixel SPX2, and the third sub-pixel SPX3 may be arranged sequentially in the second direction DR2 which intersects the first direction DR1.

The first to third sub-pixels SPX1, SPX2, and SPX3 may emit light of different colors. In one example, the first sub-pixel SPX1 may emit a first light, the second sub-pixel SPX2 may emit a second light, and the third sub-pixel SPX3 may emit a third light. The first light may be light in a red wavelength band, the second light may be light in a green wavelength band, and the third light may be light in a blue wavelength band. The red wavelength band may be a wavelength band of 600 nanometers (nm) to 750 nm (or approximately 600 nm to 750 nm), the green wavelength band may be a wavelength band of 480 nm to 560 nm (or approximately 480 nm to 560 nm), and the blue wavelength band may be a wavelength band of 370 nm to 460 nm (or approximately 370 nm to 460 nm), but embodiments of the present disclosure are not limited thereto. The color, type, and/or number of pixels constituting the pixel PXL are not particularly limited, and for example, the color of the light emitted by each of the first to third sub-pixels SPX1, SPX2, and SPX3 may be varied. Hereinafter, the first to third sub-pixels SPX1, SPX2, and SPX3 are collectively referred to as the pixel PXL.

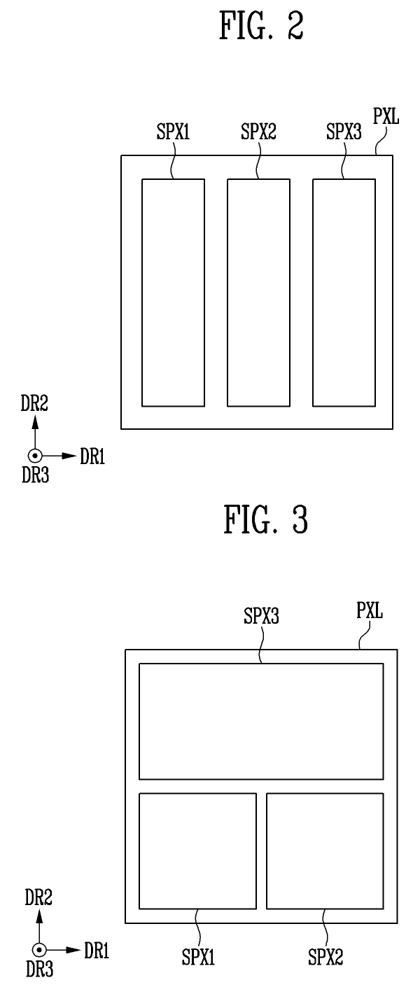

FIGS. 2 to 4 are schematic plan views illustrating embodiments of the pixel PXL of FIG. 1.

The first sub-pixel SPX1, the second sub-pixel SPX2, and the third sub-pixel SPX3 shown in FIGS. 2 to 4 may be connected to one of data lines and at least one of scan lines.

Each of the first sub-pixel SPX1, the second sub-pixel SPX2, and the third sub-pixel SPX3 may have a rectangular, square, or polygonal planar shape.

Referring to FIG. 2, each of the first sub-pixel SPX1, the second sub-pixel SPX2, and the third sub-pixel SPX3 may have a planar shape of a rectangle with the short side in the first direction DR1 and the long side in the second direction DR2. However, embodiments according to the present disclosure are not limited thereto, according to some embodiments, each of the first sub-pixel SPX1, the second sub-pixel SPX2, and the third sub-pixel SPX3 may have a planar shape of a square or rhombus with sides having equal lengths in the first direction DR1 and the second direction DR2. According to some embodiments, the first sub-pixel SPX1, the second sub-pixel SPX2, and the third sub-pixel SPX3 may be arranged in the first direction DR1. According to some embodiments, the first to third sub-pixels SPX1, SPX2, and SPX3 may have substantially the same area, but are not limited thereto. For example, at least one of the areas of the first to third sub-pixels SPX1, SPX2, or SPX3 may be different from another. Alternatively, any two of the area of the first sub-pixel SPX1, the area of the second sub-pixel SPX2, and the area of the third sub-pixel SPX3 may be substantially the same and the other may be different from the two. Alternatively, the area of the first sub-pixel SPX1, the area of the second sub-pixel SPX2, and the area of the third sub-pixel SPX3 may be different from each other.

Referring to FIG. 3, the first sub-pixel SPX1 may be arranged in the first direction DR1 with respect to one of the second sub-pixel SPX2 or the third sub-pixel SPX3 and in the second direction DR2 with the other. For example, the first sub-pixel SPX1 may be arranged side-by-side in the first direction DR1 with the second sub-pixel SPX2, and the first sub-pixel SPX1 may be arranged in the second direction DR2 with respect to the third sub-pixel SPX3. According to some embodiments, the third sub-pixel SPX3 may be arranged in the second direction DR2 with respect to the first sub-pixel SPX1 and the second sub-pixel SPX2. According to some embodiments, the areas of the first and second sub-pixels SPX1 and SPX2 are substantially equal to each other, and the area of the third sub-pixel SPX3 may be different from the areas of the first and second sub-pixels SPX1 and SPX2. For example, the area of the third sub-pixel SPX3 may be larger than each of the areas of the first and second sub-pixels SPX1 and SPX2.

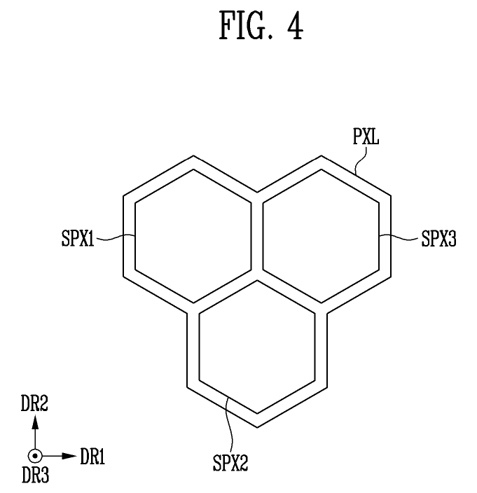

Referring to FIG. 4, each of the first sub-pixel SPX1, the second sub-pixel SPX2, and the third sub-pixel SPX3 may have a hexagonal or regular hexagonal planar shape. According to some embodiments, adjacent two faces of the six faces of each of the first to third sub-pixels SPX1 to SPX3 may face adjacent one face of each of the adjacent sub-pixels.

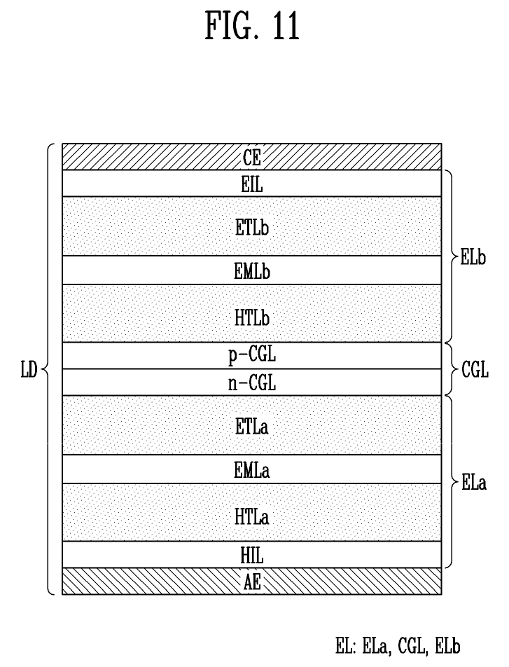

Each of the first sub-pixel SPX1, the second sub-pixel SPX2, and the third sub-pixel SPX3 may include a light emitting element which emits light (e.g., the light emitting element LD of FIGS. 10 or 11), and the light emitting element may include an organic light emitting element having an organic light emitting layer.

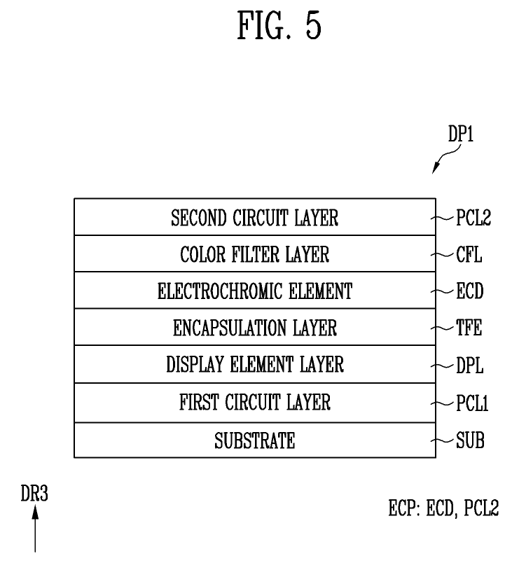

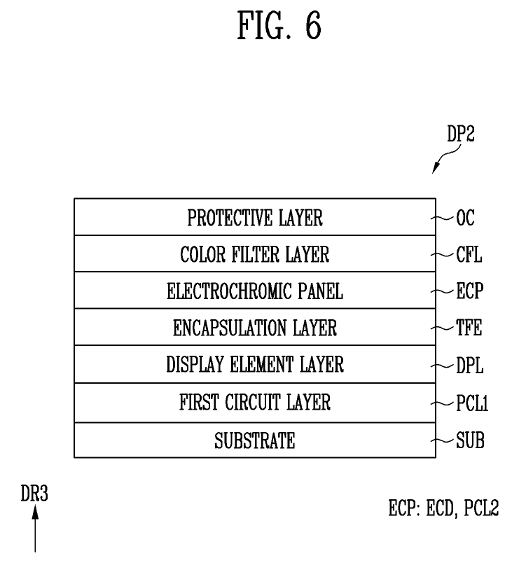

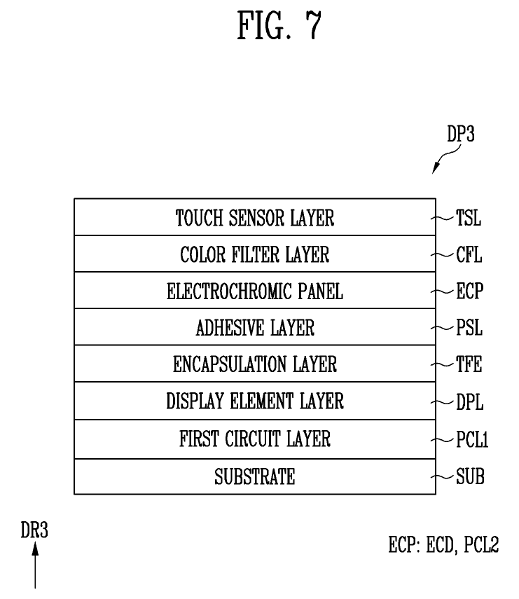

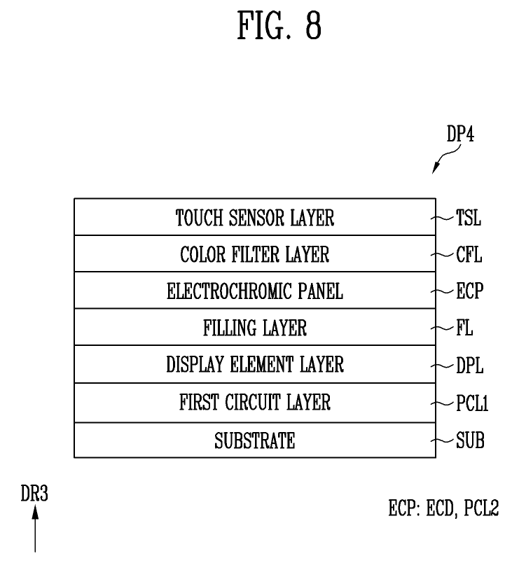

FIGS. 5 to 8 are schematic cross-sectional views of the display panel of FIG. 1 according to some embodiments. FIG. 5 is a schematic cross-sectional view showing a display panel DP1 according to some embodiments. FIG. 6 is a schematic cross-sectional view showing a display panel DP2 according to some embodiments. FIG. 7 is a schematic cross-sectional view showing a display panel DP3 according to some embodiments. FIG. 8 is a schematic cross-sectional view showing a display panel DP4 according to some embodiments.

Referring to FIG. 5, the display panel DP1 may include the substrate SUB, a first circuit layer PCL1, a display element layer DPL, an encapsulation layer TFE, an electrochromic element ECD, a color filter layer CFL, and a second circuit layer PCL2. According to some embodiments, the substrate SUB, the first circuit layer PCL1, the display element layer DPL, the encapsulation layer TFE, the electrochromic element ECD, the color filter layer CFL, and the second circuit layer PCL2 may be stacked sequentially in the third direction DR3.

The first circuit layer PCL1 is provided on the substrate SUB and may include a plurality of transistors and signal lines connected to the transistors. For example, each transistor may be in the form of a semiconductor pattern, a gate electrode, a source electrode, and a drain electrode stacked one after the other with an insulating layer therebetween, respectively. The semiconductor pattern may include at least one of amorphous silicon, poly silicon, low temperature poly silicon, an organic semiconductor, or an oxide semiconductor. The gate electrode, source electrode, and drain electrode may include, but are not limited to, at least one of aluminum (Al), copper (Cu), titanium (Ti), or molybdenum (Mo). Further, the first circuit layer PCL1 may include at least one or more insulating layers.

The first circuit layer PCL1 may be a pixel circuit layer including a pixel circuit PXC (see FIG. 9) for driving each of the first sub-pixel SPX1, the second sub-pixel SPX2, and the third sub-pixel SPX3.

The display element layer DPL may be arranged on the first circuit layer PCL1. The display element layer DPL may include a light emitting element (e.g., the light emitting element LD of FIGS. 10 or 11) which emits light. The light emitting element may be, for example, an organic light emitting diode.

The encapsulation layer TFE may be arranged on the display element layer DPL. The encapsulation layer TFE may be in the form of an encapsulation substrate or a single-layer encapsulation film. However, embodiments according to the present disclosure are not limited thereto, and the encapsulation layer TFE may have a multi-layer structure.

When the encapsulation layer TFE is in the form of a single-layer encapsulation film, the encapsulation layer TFE may include an inorganic film. However, embodiments according to the present disclosure are not limited thereto.

When the encapsulation layer TFE is in the form of a multi-layer encapsulation film, the encapsulation layer TFE may include organic and inorganic films. For example, the multi-layer encapsulation layer TFE may be in the form of an inorganic film, an organic film, and an inorganic film stacked one after the other.

The encapsulation layer TFE layer may prevent or reduce penetration of external contaminants, such as air and moisture, into the display element layer DPL and the first circuit layer PCL1.

According to some embodiments, a touch sensor layer may be further arranged on the encapsulation layer TFE. For example, the touch sensor layer may be arranged between the encapsulation layer TFE and the electrochromic element ECD. The touch sensor layer may detect a touch input from a user and convert it into an electrical signal.

The touch sensor layer may include a substrate, sensing electrodes arranged on the substrate, and insulating layers arranged between the sensing electrodes. A touch sensor layer TSL may include a touch sensor and a circuit electrically connected to the touch sensor.

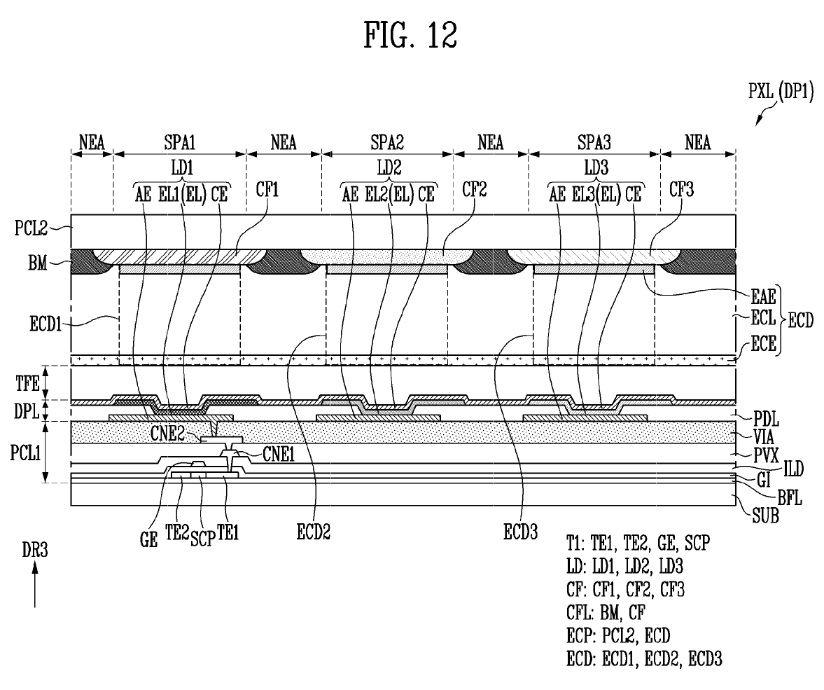

The electrochromic element ECD may be arranged on the encapsulation layer TFE. The electrochromic element ECD may have the property of changing color when a voltage is applied. For example, the electrochromic element ECD may be a device including an electrochromic layer ECL (see FIG. 12) which changes its optical properties (e.g., color or transparency) upon being oxidized or reduced by a voltage. For example, the electrochromic element ECD may be a device including the electrochromic layer ECL which darkens or lightens in color as it is oxidized or reduced in response to the application of a voltage.

The display device DD according to the present disclosure may include the electrochromic element ECD driven per sub-pixel SPX1, SPX2, or SPX3. For example, the electrochromic element ECD may include a first electrochromic element ECD1 arranged in a region overlapping the first sub-pixel SPX1 (see FIG. 12), a second electrochromic element ECD2 arranged in a region overlapping the second sub-pixel SPX2 (see FIG. 12), and a third electrochromic element ECD3 arranged in a region overlapping the third sub-pixel SPX3 (see FIG. 12), and each of the first to third electrochromic elements ECD1, ECD2, and ECD3 may be individually driven.

For example, a voltage may be applied to the first electrochromic element ECD1, while a voltage might not be applied to the second electrochromic element ECD2 and the third electrochromic element ECD3. The first electrochromic element ECD1 arranged in the region overlapping the first sub-pixel SPX1 may have different optical properties from the second electrochromic element ECD2 arranged in the region overlapping the second sub-pixel SPX2 and the third electrochromic element ECD3 arranged in the region overlapping the third sub-pixel SPX3. For example, the color of the first electrochromic element ECD1 may be different from the colors of the second electrochromic element ECD2 and the third electrochromic element ECD3.

The color filter layer CFL may be arranged on the electrochromic element ECD. The color filter layer CFL may selectively transmit light which has passed through the display element layer DPL. The color filter layer CFL may include first to third color filters CF1, CF2, and CF3 (see FIG. 12).

The second circuit layer PCL2 may be arranged on the color filter layer CFL. The second circuit layer PCL2 may include a plurality of transistors arranged on the substrate and signal lines connected to the transistors.

The second circuit layer PCL2 may be a layer electrically connected to the electrochromic element ECD. For example, the second circuit layer PCL2 may be a circuit layer which includes a circuit for driving (or operating) each of the first electrochromic element ECD1, the second electrochromic element ECD2, and the third electrochromic element ECD3. For example, the second circuit layer PCL2 may include a first electrochromic element circuit electrically connected to the first electrochromic element ECD1, a second electrochromic element circuit electrically connected to the second electrochromic element ECD2, and a third electrochromic element circuit electrically connected to the third electrochromic element ECD3.

The first electrochromic element circuit, the second electrochromic element circuit, and the third electrochromic element circuit may drive the first electrochromic element ECD1, the second electrochromic element ECD2, and the third electrochromic element ECD3, respectively. For example, the first electrochromic element circuit, the second electrochromic element circuit, and the third electrochromic element circuit may apply a voltage to the first electrochromic element ECD1, the second electrochromic element ECD2, and the third electrochromic element ECD3, respectively. Accordingly, the first electrochromic element ECD1, the second electrochromic element ECD2, and the third electrochromic element ECD3 may be configured to be driven individually.

The electrochromic element ECD may be electrically connected to the second circuit layer PCL2 through a contact hole penetrating the color filter layer CFL, and may receive an electrical signal (or voltage) from the second circuit layer PCL2. Hereinafter, the electrochromic element ECD and the second circuit layer PCL2 are defined as an electrochromic panel ECP. For example, the electrochromic panel ECP may include the electrochromic element ECD and the second circuit layer PCL2.

According to the display panel DP1 as illustrated in FIG. 5, with respect to the color filter layer CFL, the second circuit layer PCL2 of the electrochromic panel ECP may be arranged on the color filter layer CFL, and the electrochromic element ECD of the electrochromic panel ECP may be arranged under the color filter layer CFL. Hereinafter, an upper direction may be defined as the direction in which the third direction DR3 is oriented.

Referring to FIG. 6, the display panel DP2 according to some embodiments differs from the display panel DP1 according to the embodiments illustrated with respect to FIG. 5 in that the electrochromic panel ECP is arranged between the encapsulation layer TFE and the color filter layer CFL, and further includes a protective layer OC.

The electrochromic panel ECP may be arranged between the encapsulation layer TFE and the color filter layer CFL. For example, the electrochromic element ECD and the second circuit layer PCL2 may be arranged between the encapsulation layer TFE and the color filter layer CFL. The protective layer OC may be arranged on the color filter layer CFL.

The protective layer OC may offset the step difference of the color filter layer CFL and protect the configuration arranged below the protective layer OC. The protective layer OC may be an overcoat layer or a film layer, according to some embodiments. The protective layer OC may be an inorganic layer including at least one of a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), or a titanium oxide (TiOx), according to some embodiments. However, embodiments according to the present disclosure are not limited thereto. For example, the protective layer OC may include an organic layer. For example, the protective layer OC may be an organic layer including at least one of an acrylic resin, an epoxy resin, a phenol resin, a polyamide resin, a polyimide resin, an unsaturated polyester resin, a poly-phenylene ether resin, a poly-phenylene sulfide resin, or a benzocyclobutene resin.

Referring to FIG. 7, the display panel DP3 according to some embodiments differs from the display panel DP1 according to the embodiments illustrated with respect to FIG. 5 in that the electrochromic panel ECP is attached to the encapsulation layer TFE via an adhesive layer PSL, and the touch sensor layer TSL is arranged on the color filter layer CFL.

The electrochromic panel ECP may be arranged between the encapsulation layer TFE and the color filter layer CFL. For example, the electrochromic element ECD and the second circuit layer PCL2 may be arranged between the encapsulation layer TFE and the color filter layer CFL.

The electrochromic panel ECP may be attached to the encapsulation layer TFE via the adhesive layer PSL. For example, the adhesive layer PSL may be arranged on the encapsulation layer TFE and the electrochromic panel ECP may be arranged on the adhesive layer PSL. The electrochromic panel ECP may be arranged between the adhesive layer PSL and the color filter layer CFL.

The adhesive layer PSL may include at least one of an optically clear adhesive (OCA), an optically clear resin (OCR), or a pressure sensitive adhesive (PSA). However, embodiments according to the present disclosure are not limited thereto.

The touch sensor layer TSL may be arranged on the color filter layer CFL.

Referring to FIG. 8, the display panel DP4 according to some embodiments differs from the display panel DP3 illustrated and described with respect to FIG. 7 in that a filling layer FL is arranged in place of the adhesive layer PSL and the encapsulation layer TFE.

The filling layer FL may be arranged between the display element layer DPL and the electrochromic panel ECP. The filling layer FL may be a vacuum layer composed of a vacuum or a layer including a filler. The filler may include at least one of an organic material or an inorganic material capable of transmitting light.

FIG. 9 is a schematic diagram of aspects of an equivalent circuit of a sub-pixel SPX included in a pixel of FIGS. 2 to 4. Although FIG. 9 illustrates various components in a sub-pixel according to some embodiments, embodiments according to the present disclosure are not limited thereto, and according to various embodiments, the sub-pixel may include additional components, or fewer components, without departing from the spirit and scope of embodiments according to the present disclosure.

The sub-pixel SPX shown in FIG. 9 may be one of the sub-pixels SPX1, SPX2, or SPX3 shown in FIG. 1, and the sub-pixels SPX1, SPX2, and SPX3 arranged in the display area of each display device DD may be substantially identically or similarly configured to each other.

For convenience, FIG. 9 shows the sub-pixel SPX located in an i-th pixel row (or i-th horizontal line) and a j-th pixel column (where i and j are natural numbers).

Referring to FIG. 9, the sub-pixel SPX may include an emission element EMU which generates light of luminance corresponding to a data signal. The sub-pixel SPX may further include the pixel circuit PXC for driving the emission element EMU.

The emission element EMU may include the light emitting element LD connected between a first power line PL1 supplied with a voltage of a first driving power source VDD (or first power source) and a second power line PL2 supplied with a voltage of a second driving power source VSS (or second power source). In one example, the emission element EMU may include the light emitting element LD including a first electrode AE connected to the first driving power source VDD via the pixel circuit PXC and the first power line PL1 and a second electrode CE connected to the second driving power source VSS via the second power line PL2. The first electrode AE may be an anode, and the second electrode CE may be a cathode. The first driving power source VDD and the second driving power source VSS may have different potentials. The potential difference between the first and second driving power sources VDD and VSS may be set above a threshold voltage of the light emitting element LD during an emission period of the sub-pixel SPX.

When the sub-pixel SPX is located in the i-th pixel row and the j-th pixel column in the display area DA, the pixel circuit PXC of the sub-pixel SPX (or the sub-pixel) may be electrically connected to an i-th scan line Si and a j-th data line Dj. Further, the pixel circuit PXC may be electrically connected to an i-th control line CLi and a j-th sensing line SENj.

The pixel circuit PXC described above may include first to third transistors T1, T2, and T3 and a storage capacitor Cst.

The first transistor T1 may be electrically connected between the first driving power source VDD and the light emitting element LD as a driving transistor for controlling a driving current applied to the light emitting element LD. Specifically, a first terminal of the first transistor T1 may be electrically connected to the first driving power source VDD via the first power line PL1, a second terminal of the first transistor T1 may be electrically connected to a second node N2, and a gate electrode of the first transistor T1 may be electrically connected to a first node N1. The first transistor T1 may control the amount of driving current applied to the light emitting element LD from the first driving power source VDD through the second node N2 according to a voltage applied to the first node N1. According to some embodiments, the first terminal of the first transistor T1 may be a drain electrode and the second terminal of the first transistor T1 may be a source electrode, but embodiments according to the present disclosure are not limited thereto. According to some embodiments, the first terminal may be a source electrode and the second terminal may be a drain electrode.

The second transistor T2 may be electrically connected between the data line Dj (e.g., the j-th data line) and the first node N1 as a switching transistor which selects the sub-pixel SPX in response to a scan signal and activates the sub-pixel SPX. A first terminal of the second transistor T2 may be electrically connected to the data line Dj, a second terminal of the second transistor T2 may be electrically connected to the first node N1 (or the gate electrode of the first transistor T1), and a gate electrode of the second transistor T2 may be electrically connected to the scan line Si (or the i-th scan line). The first terminal and the second terminal of the second transistor T2 may be different terminals, for example, the first terminal may be a drain electrode and the second terminal may be a source electrode.

The second transistor T2 as described above may be turned on when a scan signal of a gate-on voltage (e.g., a high-level voltage) is supplied from the scan line Si, thereby electrically connecting the data line Dj and the first node N1. The first node N1 is a point where the second terminal of the second transistor T2 and the gate electrode of the first transistor T1 are connected, and the second transistor T2 may transfer a data signal to the gate electrode of the first transistor T1.

The third transistor T3 may electrically connect the first transistor T1 to the sensing line SENj (e.g., the j-th sensing line) to obtain a sensing signal through the sensing line SENj, and may use the sensing signal to detect characteristics of the sub-pixel SPX, such as a threshold voltage of the first transistor T1. The information about the characteristics of the sub-pixels SPX may be used to convert the image data so that the deviation of the characteristics between the sub-pixels SPX may be compensated. A second terminal of the third transistor T3 may be electrically connected to the second terminal of the first transistor T1, a first terminal of the third transistor T3 may be electrically connected to the sensing line SENj, and a gate electrode of the third transistor T3 may be electrically connected to the control line CLi (e.g., the i-th control line). The first terminal may be a drain electrode, and the second terminal may be a source electrode.

The third transistor T3 is an initialization transistor capable of initializing the second node N2, which can be turned on when a sensing control signal is supplied from the control line CLi and transfer a voltage of an initialization power source to the second node N2. Accordingly, the storage capacitor Cst electrically connected to the second node N2 may be initialized.

The storage capacitor Cst may include a lower electrode LE (or first storage electrode) and an upper electrode UE (or second storage electrode). The lower electrode LE may be electrically connected to the first node N1, and the upper electrode UE may be electrically connected to the second node N2. The storage capacitor Cst as described above charges a data voltage corresponding to the data signal supplied to the first node N1 during one frame period. Accordingly, the storage capacitor Cst may store a voltage corresponding to the difference between a voltage of the gate electrode of the first transistor T1 and a voltage of the second node N2.

Although FIG. 9 illustrates aspects of embodiments in which the first to third transistors T1, T2, and T3 are all N-type transistors, but the first to third transistors T1, T2, and T3 according to the present disclosure are not limited thereto. For example, at least one of the first to third transistors T1, T2, or T3 may be changed to a P-type transistor. The structure of the pixel circuit PXC may be implemented in various modified forms.

FIG. 10 is a cross-sectional view illustrating further details of the light emitting element LD of FIG. 9. FIG. 11 is a cross-sectional view illustrating further details of the light emitting element LD of FIG. 9.

Referring to FIG. 10, the light emitting element LD may include the first electrode AE, an organic light emitting element EL, and the second electrode CE. According to some embodiments, the first electrode AE, the organic light emitting element EL, and the second electrode CE may be stacked sequentially.

According to some embodiments, the first electrode AE may be patterned to correspond to the first to third sub-pixels SPX1, SPX2, and SPX3.

According to some embodiments, the organic light emitting element EL may be provided on the first electrode AE. The organic light emitting element EL may be in contact with the first electrode AE. The organic light emitting element EL may have a multilayer thin film structure including a plurality of light generation layers. The organic light emitting element EL may include a hole injection layer HIL, a hole transport layer HTL, an emission layer EML, an electron transport layer ETL, and an electron injection layer EIL stacked sequentially.

The hole injection layer HIL may be an organic layer arranged between the first electrode AE and the hole transport layer HTL to facilitate the injection of holes from the first electrode AE into the emission layer EML. The hole transport layer HTL may be arranged between the hole injection layer HIL and the emission layer EML to receive holes from the first electrode AE and transport the holes to the emission layer EML.

The electron injection layer EIL may be arranged between the electron transport layer ETL and the second electrode CE. The electron transport layer ETL may be arranged on the emission layer EML to receive electrons from the second electrode CE and transport the electrons to the emission layer EML.

The emission layer EML is the region where light is generated by the combination of electrons and holes supplied from the first electrode AE and the second electrode CE. The emission layer EML may include an organic light emitting material, such as a polymeric organic material or a small-molecule organic material which emits light of a color (e.g., a set or predetermined color). For example, the emission layer EML may include an organic material which emits red, green, or blue light. However, embodiments according to the present disclosure are not limited to these.

According to some embodiments, the second electrode CE may be integrally formed. The second electrode CE may be arranged on the organic light emitting element EL. The second electrode CE may be formed as a single unit in the light emitting element LD.

Referring to FIG. 11, according to some embodiments, the organic light emitting element EL may include the plurality of light generation layers. According to some embodiments, the organic light emitting element EL may include a first organic light emitting element ELa, a charge generation layer CGL, and a second organic light emitting element ELb. According to some embodiments, the first electrode AE, the first organic light emitting element ELa, the charge generation layer CGL, the second organic light emitting element ELb, and the second electrode CE may be stacked sequentially.

The first organic light emitting element ELa may have a structure in which the hole injection layer HIL, a first hole transport layer HTLa, a first organic light emitting layer EMLa, and a first electron transport layer ETLa are stacked sequentially. The second organic light emitting element ELb may have a structure in which a second hole transport layer HTLb, a second organic light emitting layer EMLb, a second electron transport layer ETLb, and the electron injection layer EIL stacked one after the other.

According to some embodiments, a buffer layer (not shown) may be arranged between the first organic light emitting layer EMLa and the second organic light emitting layer EMLb. The buffer layer may include an electron transporting compound.

The charge generation layer CGL may serve to supply charge to the first organic light emitting element ELa and the second organic light emitting element ELb. The charge generation layer CGL may include an n-type charge generation layer n-CGL for supplying charge to the first organic light emitting element ELa and a p-type charge generation layer p-CGL for supplying holes to the second organic light emitting element ELb. The n-type charge generation layer n-CGL may include a metallic material as a dopant.

FIG. 11 shows that two organic light emitting elements ELa and ELb of the light emitting element LD are stacked, but embodiments according to the present disclosure are not limited thereto. For example, three, four or more organic light emitting portions may be stacked within the light emitting element LD.

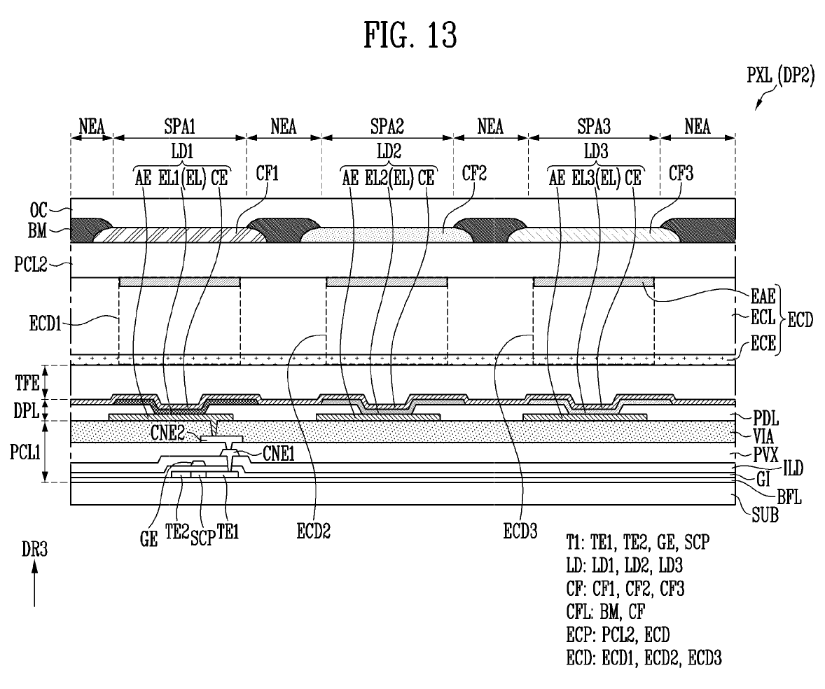

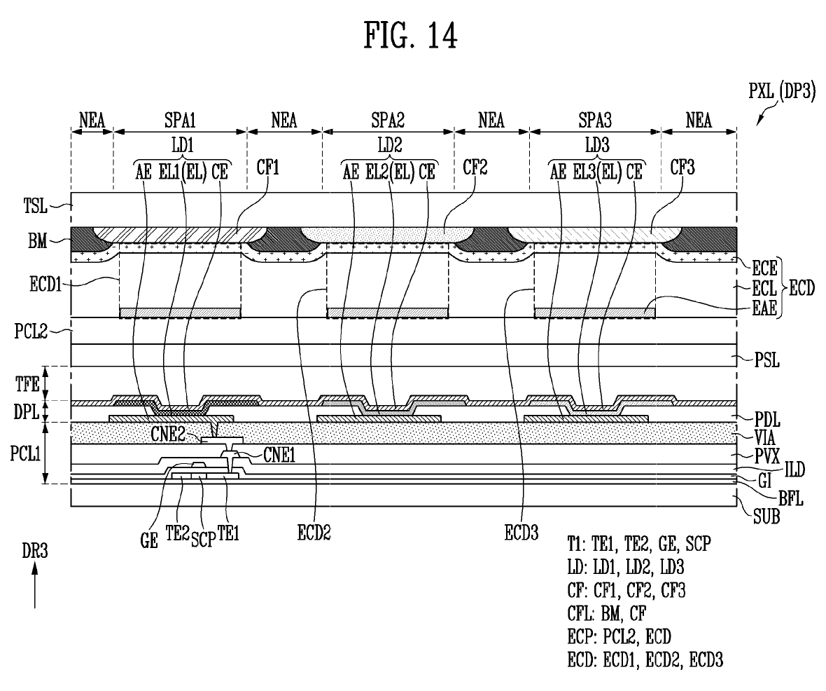

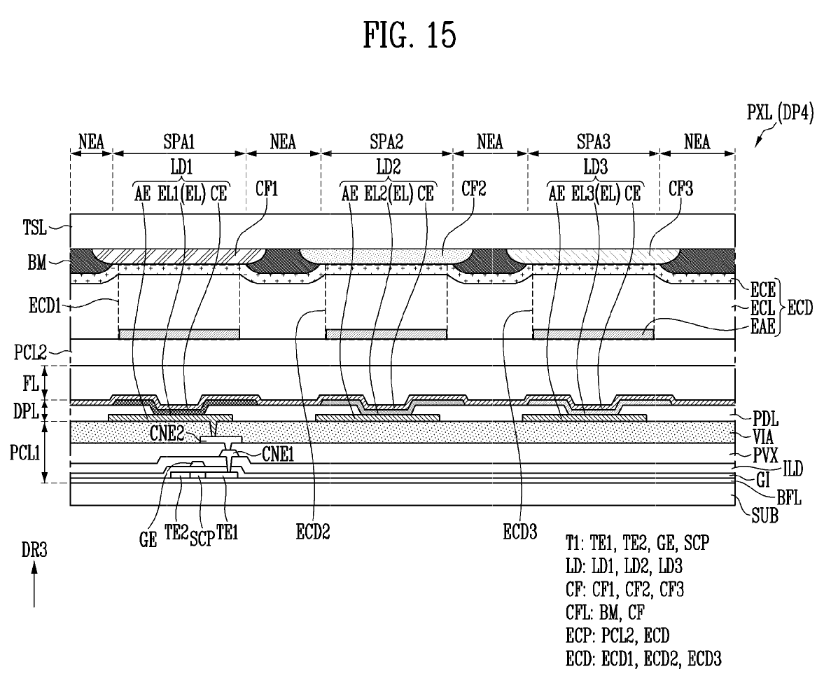

FIGS. 12 to 15 are schematic cross-sectional views of a pixel according to some embodiments. FIG. 12 may be a schematic cross-sectional view of the display panel DP1 of FIG. 5. FIG. 13 may be a schematic cross-sectional view of the display panel DP2 of FIG. 6. FIG. 14 may be a schematic cross-sectional view of the display panel DP3 of FIG. 7. FIG. 15 may be a schematic cross-sectional view of the display panel DP4 of FIG. 8.

First, with reference to FIG. 12, further details of the display panel DP1 as illustrated and described with respect to FIG. 5 will be described.

Referring to FIGS. 1, 5 and 12, the display device DD includes the display area DA, which may include first to third sub-pixel areas SPA1, SPA2, and SPA3, and a non-emission area NEA. According to some embodiments, the first sub-pixel area SPA1 may be an area from which light of the first color of the first sub-pixel SPX1 is emitted. The second sub-pixel area SPA2 may be an area from which light of the second color of the second sub-pixel SPX2 is emitted. The third sub-pixel area SPA3 may be an area from which light of the third color of the third sub-pixel SPX3 is emitted. For example, the first sub-pixel area SPA1 may emit light in the red wavelength band, the second sub-pixel area SPA2 may emit light in the green wavelength band, and the third sub-pixel area SPA3 may emit light in the blue wavelength band.

According to some embodiments, emission areas of the display area DA may correspond to the first to third sub-pixel areas SPA1, SPA2, and SPA3. The first to third sub-pixel areas SPA1, SPA2, and SPA3 and the non-emission area NEA may be defined by a black matrix BM of the color filter layer CFL.

According to some embodiments, the pixel PXL may include the first circuit layer PCL1, the display element layer DPL, the encapsulation layer TFE, the electrochromic element ECD, the color filter layer CFL, and the second circuit layer PCL2 arranged sequentially in the third direction DR3 on the substrate SUB.

The first circuit layer PCL1 may include circuit elements (e.g., the first to third transistors T1, T2, and T3 of FIG. 9) and signal lines electrically connected to the circuit elements. The first circuit layer PCL1 may be arranged on the substrate SUB. The first circuit layer PCL1 may include the first transistor T1, a buffer layer BFL, a gate insulating layer GI, an interlayer insulating layer ILD, a passivation layer PVX, and a via layer VIA. While a single first transistor T1 is shown as an example, the sub-pixel SPX may include a plurality of transistors and at least one capacitor to drive the light emitting element LD.

The buffer layer BFL may be arranged on the substrate SUB. The buffer layer BFL may prevent or reduce contaminants or impurities diffusing from the outside. The buffer layer BFL may improve the flatness of the substrate SUB by preventing or reducing contaminants or impurities diffusing into the first transistor T1 provided on the substrate SUB. The buffer layer BFL may be provided as a single layer, but may also be provided as multiple layers. The buffer layer BFL may be an inorganic insulating layer including an inorganic material. The inorganic insulating layer may include at least one of metal oxides, for example, a silicon nitride (SiNx), a silicon oxide (SiOx), a silicon oxynitride (SiOxNy), or an aluminum oxide (AlOx). When the buffer layer BFL is provided in multiple layers, the respective layers may be formed of the same material or may be formed of different materials. The buffer layer BFL may be omitted in some cases.

The first transistor T1 may include a semiconductor pattern SCP, a gate electrode GE, a first terminal TE1, and a second terminal TE2. The first terminal TE1 may be one of a source electrode or a drain electrode, and the second terminal TE2 may be the other of the above-mentioned two electrodes. In one example, when the first terminal TE1 is a drain electrode, the second terminal TE2 may be a source electrode.

The semiconductor pattern SCP may be provided and/or formed on the buffer layer BFL. The semiconductor pattern SCP may include a first region in contact with the first terminal TE1, a second region in contact with the second terminal TE2, and a channel region between the first region and the second region. The channel region may overlap with the gate electrode GE of the first transistor T1. The semiconductor pattern SCP may be a semiconductor pattern composed of amorphous silicon, polysilicon, low-temperature polysilicon, an oxide semiconductor, an organic semiconductor, or the like. The channel region may be, for example, an intrinsic semiconductor which is a semiconductor pattern which is not doped with impurities. The first region and the second region may be semiconductor patterns which are doped with impurities. According to some embodiments, the first terminal TE1 may be electrically connected to the light emitting element LD via connecting electrodes CNE1 and CNE2.

The gate insulating layer GI may be provided (or formed) on the semiconductor pattern SCP. The gate insulating layer GI may be an inorganic insulating layer including an inorganic material. The gate insulating layer GI may include the same material as the buffer layer BFL or may include one or more materials selected from the materials described as components of the buffer layer BFL. According to some embodiments, the gate insulating layer GI may be provided as an organic insulating layer including an organic material. The gate insulating layer GI may be provided as a single layer, but may be provided as multiple layers of at least two layers.

The gate electrode GE may be provided (or formed) on the gate insulating layer GI to correspond to the channel region of the semiconductor pattern SCP. The gate electrode GE may be provided on the gate insulating layer GI to overlap with the channel region of the semiconductor pattern SCP. The gate electrode GE may be formed as a single layer using a single material or a mixture of materials selected from the group consisting of copper (Cu), molybdenum (Mo), tungsten (W), aluminum neodymium (AlNd), titanium (Ti), aluminum (Al), silver (Ag), and alloys thereof, or may be formed as a dual-layer or multi-layer structure using low-resistance materials, such as molybdenum (Mo), titanium (Ti), copper (Cu), aluminum (Al), or silver (Ag) to reduce wiring resistance.

The interlayer insulating layer ILD may be provided (or formed) on the gate electrode GE. The first connecting electrode CNE1 may be arranged on the interlayer insulating layer ILD. The first connecting electrode CNE1 may be electrically connected to the first terminal TE1 via a contact hole penetrating the gate insulating layer GI and the interlayer insulating layer ILD.

The passivation layer PVX may be provided (or formed) on the first connecting electrode CNE1. The second connecting electrode CNE2 may be arranged on the passivation layer PVX. The second connecting electrode CNE2 may be electrically connected to the first connecting electrode CNE1 via a contact hole (not shown) penetrating the passivation layer PVX.

The passivation layer PVX may be provided in the form of including an inorganic insulating layer arranged on an organic insulating layer or an organic insulating layer arranged on an inorganic insulating layer. The inorganic insulating layer may include, for example, at least one of metal oxides, such as a silicon oxide (SiOx), a silicon nitride (SiNx), a silicon oxynitride (SiOxNy), or an aluminum oxide (AlOx). The organic insulating layer may include, for example, at least one of an acrylic resin, an epoxy resin, a phenol resin, a polyamide resin, a polyimide resin, an unsaturated polyester resin, a poly-phenylene ether resin, a poly-phenylene sulfide resin, or a benzocyclobutene resin.

The via layer VIA may be provided (or formed) entirely on the passivation layer PVX. The via layer VIA may be an inorganic insulating layer including inorganic materials or an organic insulating layer including organic materials.

The display element layer DPL may be arranged on the via layer VIA. The display element layer DPL may include the light emitting element LD and a pixel defining layer PDL. The light emitting element LD and the pixel defining layer PDL may be provided (or formed) on the via layer VIA. The light emitting element LD may include a first light emitting element LD1 arranged in the first sub-pixel area SPA1, a second light emitting element LD2 arranged in the second sub-pixel area SPA2, and a third light emitting element LD3 arranged in the third sub-pixel area SPA3.

Each of the light emitting elements LD may include the first electrode AE, the organic light emitting element EL, and the second electrode CE. For example, the first light emitting element LD1 may include the first electrode AE, a first organic light emitting element EL1 emitting light of the first color, and the second electrode CE. The second light emitting element LD2 may include the first electrode AE, a second organic light emitting element EL2 emitting light of the second color, and the second electrode CE. The third light emitting element LD3 may include the first electrode AE, a third organic light emitting element EL3 emitting light of the third color, and the second electrode CE. However, embodiments according to the present disclosure are not limited thereto. For example, the light emitting elements LD may emit light of the same color.

The light emitting element LD may be electrically connected to a pixel circuit of the corresponding pixel (e.g., the pixel circuit PXC of FIG. 9).

The first electrode AE may be provided (or formed) on the via layer VIA of the corresponding pixel. The first electrode AE may be an anode electrode of the light emitting element LD. The first electrode AE may be electrically connected to the first terminal TE1 via a contact portion (not shown). According to some embodiments, the first electrode AE may include anode electrodes corresponding to the first to third sub-pixel areas SPA1, SPA2, and SPA3. The first electrode AE may be patterned to correspond to the first to third sub-pixel areas SPA1, SPA2, and SPA3.

Each first electrode AE may be made of a conductive substance (or material). The conductive substance may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the material of each of the first electrodes AE is not limited to the embodiments described above. In some embodiments, the first electrode AE may include a transparent conductive substance (or material). The transparent conductive substance (or material) may include a conductive oxide, such as an indium tin oxide (ITO), an indium zinc oxide (IZO), a zinc oxide (ZnOx), an indium gallium zinc oxide (IGZO), or an indium tin zinc oxide (ITZO), and a conductive polymer, such as poly(3,4-ethylenedioxythiophene) (PEDOT). When the first electrode AE includes a transparent conductive substance (or material), a separate conductive layer of an opaque metal may be added to reflect light emitted from the organic light emitting element EL in the direction of the image display (or the encapsulation layer TFE) of a display device (e.g., display device DD in FIG. 1).

The pixel defining layer PDL may define (or compartmentalize) the region in which the organic light emitting element EL is arranged. The pixel defining layer PDL may expose at least one region of the first electrode AE. The pixel defining layer PDL may be an organic insulating layer made of an organic material. According to some embodiments, the pixel defining layer PDL may include a light absorbing substance, or may be coated with a light absorber to act as an absorber of light introduced from the outside. For example, the pixel defining layer PDL may include a carbon-based black pigment. However, embodiments according to the present disclosure are not a limited thereto. According to some embodiments, the pixel defining layer PDL may be an inorganic insulating layer made of an inorganic material.

The pixel defining layer PDL may be partially opened to include an opening exposing a region of the first electrode AE, and may protrude from the via layer VIA in the third direction DR3 along the perimeter of the emission area. The pixel defining layer PDL may be arranged on the via layer VIA to define a region in which the organic light emitting element EL is arranged and received on the first electrode AE. The organic light emitting element EL may be arranged on the first electrode AE exposed by the opening in the pixel defining layer PDL.

The organic light emitting element EL may have a multilayer thin film structure including a light generation layer which generates light. The organic light emitting element EL may emit one of red light, green light, or blue light, but is not limited thereto. For example, the organic light emitting element EL may include a white emission layer which emits white light. The internal design of the organic light emitting element EL may also vary depending on the color of light which is desired to be emitted.

The second electrode CE may be arranged on the organic light emitting element EL and the pixel defining layer PDL. The second electrode CE may be provided in the form of a plate across the entire area of the display area DA. The second electrode CE may be arranged at the outermost (or uppermost) edge of the light emitting element LD.

The second electrode CE may be a thin metal layer having a thickness sufficient to transmit light emitted from the organic light emitting element EL. The second electrode CE may be formed of a metallic material to have a relatively small thickness or may consist of a transparent conductive material. According to some embodiments, the second electrode CE may include two or more metal layers, but embodiments according to the present disclosure are not limited thereto. The second electrode CE may include at least one of various transparent conductive materials, including an indium tin oxide, an indium zinc oxide, an indium tin zinc oxide, an aluminum zinc oxide, a gallium zinc oxide, a zinc tin oxide, or a gallium tin oxide, and may be implemented to be substantially transparent or translucent to meet the light transmittance (e.g., a set or predetermined light transmittance). Accordingly, light emitted from the organic light emitting element EL located under the second electrode CE may pass through the second electrode CE and be emitted in the upper direction of the encapsulation layer TFE.

The encapsulation layer TFE may be provided (or formed) entirely on the second electrode CE. The encapsulation layer TFE may be in contact with the second electrode CE.

The encapsulation layer TFE may be an inorganic layer including an inorganic material. The encapsulation layer TFE may protect the sub-pixel SPX from foreign matter, such as dust particles. The encapsulation layer TFE may include at least one of a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), or a titanium oxide (TiOx). However, embodiments according to the present disclosure are not limited thereto.

The electrochromic element ECD may be arranged on the encapsulation layer TFE. The electrochromic element ECD may include the first electrochromic element ECD1 arranged to overlap with the first light emitting element LD1, the second electrochromic element ECD2 arranged to overlap with the second light emitting element LD2, and the third electrochromic element ECD3 arranged to overlap with the third light emitting element LD3.

Each of the first electrochromic element ECD1, the second electrochromic element ECD2, and the third electrochromic element ECD3 may include a first electrochromic element electrode ECE, the electrochromic layer ECL, and a second electrochromic element electrode EAE. According to some embodiments, the first electrochromic element electrode ECE may be arranged on the encapsulation layer TFE, the electrochromic layer ECL may be arranged on the first electrochromic element electrode ECE, and the second electrochromic element electrode EAE may be arranged on the electrochromic layer ECL.

The first electrochromic element electrode ECE may be a cathode electrode of the electrochromic element ECD, and the second electrochromic element electrode EAE may be an anode electrode of the electrochromic element ECD. However, embodiments according to the present disclosure are not limited thereto. According to some embodiments, the first electrochromic element electrode ECE may be an anode electrode of the electrochromic element ECD and the second electrochromic element electrode EAE may be a cathode electrode of the electrochromic element ECD.

The first electrochromic element electrode ECE and the second electrochromic element electrode EAE may include a transparent conductive substance (or material). The first electrochromic element electrode ECE and the second electrochromic element electrode EAE may be electrically connected to at least two lines.

The first electrochromic element electrode ECE may be formed as a single unit (or formed integrally) with respect to the electrochromic elements ECD. For example, the first electrochromic element electrode ECE may be formed across the first to third sub-pixel areas SPA1, SPA2, and SPA3.

According to some embodiments, the first electrochromic element electrode ECE may include two or more metal layers. However, embodiments according to the present disclosure are not limited thereto.

The second electrochromic element electrode EAE may be patterned to correspond to the first to third sub-pixels SPX1, SPX2, and SPX3. According to some embodiments, the second electrochromic element electrode EAE may be patterned to have the same size and shape in each of the first electrochromic element ECD1, the second electrochromic element ECD2, and the third electrochromic element ECD3. However, embodiments according to the present disclosure are not limited thereto. The second electrochromic element electrode EAE may be patterned to have a different size and shape in at least one or more of the first electrochromic element ECD1, the second electrochromic element ECD2, and the third electrochromic element ECD3 than in the remaining electrochromic elements.

The electrochromic layer ECL may include an electrochromic substance. For example, the electrochromic substance may include oxides of metals such as tungsten, iridium, nickel, and vanadium, organic compounds such as viologens and quinones, or conductive polymers such as polythiophene, polyaniline, and polypyrrole. The electrochromic layer ECL may change color depending on whether a voltage is applied. For example, the electrochromic layer ECL may darken when a voltage is applied and lighten (e.g., become transparent) when no voltage is applied. Alternatively, the electrochromic layer ECL may lighten when a voltage is applied and darken when no voltage is applied. The electrochromic layer ECL may absorb light when darkened and allow light to pass through when lightened.

When a voltage is applied to the electrochromic element ECD, the region of the electrochromic layer ECL which changes color may overlap with a region in which an electrode of the electrochromic element ECD (e.g., the second electrochromic element electrode EAE) is arranged. For example, when a voltage is applied to the electrochromic element ECD, the color of the electrochromic layer ECL overlapping the second electrochromic element electrode EAE may change.

The shape and planar area of the region of the electrochromic layer ECL which changes color may be determined by the shape and planar area of the electrode of the electrochromic element ECD (e.g., the second electrochromic element electrode EAE). According to some embodiments, in the first to third sub-pixel areas SPA1 to SPA3, the shape and area of the region of the electrochromic layer ECL which changes color may be adjusted according to the shape of the second electrochromic element electrode EAE. For example, when the second electrochromic element electrode EAE is patterned to have different areas in the first to third sub-pixel areas SPA1 to SPA3, the area of the region of the electrochromic layer ECL which changes color may be different in the first to third sub-pixel areas SPA1 to SPA3.

Whether to apply a voltage to the electrochromic element ECD may be determined based on the intensity of external light. For example, the external light may be detected by a light sensor and whether to apply a voltage to the electrochromic element ECD may be determined. However, embodiments according to the present disclosure are not limited thereto. Whether to apply a voltage to the electrochromic element ECD may also be determined manually by a user.

In a case where the color of the electrochromic element ECD darkens when a voltage is applied to the electrochromic element ECD, the voltage may be applied to at least one of the first electrochromic element ECD1, the second electrochromic element ECD2, or the third electrochromic element ECD3 in an environment with strong external light (e.g., outdoors), and the color of the electrochromic element ECD to which the voltage is applied may darken. Alternatively, in a case where the color of the electrochromic element ECD lightens when a voltage is applied to the electrochromic element ECD, no voltage may be applied to at least one of the first electrochromic element ECD1, the second electrochromic element ECD2, or the third electrochromic element ECD3 in an environment with strong external light (e.g., outdoors), and the color of the electrochromic element ECD to which no voltage is applied may darken.

As such, the display device DD may be configured to darken at least one of the first electrochromic element ECD1, the second electrochromic element ECD2, or the third electrochromic element ECD3 in an environment with strong external light. In this case, the light emitting element LD may be turned off and not generate light, and the display device DD may be used as a reflective display device using external light. The external light which passes through a color filter CF may be absorbed by the electrochromic element ECD or may pass through the electrochromic element ECD depending on whether a voltage is applied to the electrochromic element ECD, and the display device DD may be used as a reflective display device capable of expressing colors other than black and white.

On the other hand, in an environment where the external light is not strong (e.g., indoors), the first electrochromic element ECD1, the second electrochromic element ECD2, and the third electrochromic element ECD3 may be set to lighten. In this case, the light emitting element LD may be turned on and generate light, and the display device DD may be used as a self-emissive-type display device utilizing the light emitting element LD.

As such, the display device DD may be capable of switching from a self-emissive display device to a reflective display device or from a reflective display device to a self-emissive display device, depending on the intensity of external light. According to some embodiments, when the display device DD is used as a reflective display device, the display panel DP may display an image or video that requires driving at 2 Hz or less. Accordingly, the display device DD may be driven using low power.

The color filter layer CFL may be arranged on the electrochromic element ECD. According to some embodiments, a transparent inorganic layer may be further arranged between the second electrochromic element electrode EAE of the electrochromic element ECD and the color filter layer CFL (e.g., color filter CF). The transparent inorganic layer may be a transparent inorganic layer including at least one of a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), or a titanium oxide (TiOx). However, embodiments according to the present disclosure are not limited thereto.

The color filter layer CFL may include the color filters CF and the black matrix BM. The color filters CF may include the first to third color filters CF1, CF2, and CF3 corresponding to the first to third sub-pixel areas SPA1, SPA2, and SPA3, respectively.

According to some embodiments, the first color filter CF1, the second color filter CF2, and the third color filter CF3 may be, but are not necessarily limited to, a red color filter, a green color filter, and a blue color filter, respectively.

The first color filter CF1 may overlap with the first sub-pixel area SPA1 in a plan view. The first color filter CF1 may include a color filter material which selectively transmits light of the first color (or red color). For example, when the first sub-pixel area SPA1 is a red sub-pixel area, the first color filter CF1 may include a red color filter material.

The second color filter CF2 may overlap with the second sub-pixel area SPA2 in a plan view. The second color filter CF2 may include a color filter material which selectively transmits light of the second color (or green color). For example, when the second sub-pixel area SPA2 is a green sub-pixel area, the second color filter CF2 may include a green color filter material.

The third color filter CF3 may overlap with the third sub-pixel area SPA3 in a plan view. The third color filter CF3 may include a color filter material which selectively transmits light of the third color (or blue color). For example, when the third sub-pixel area SPA3 is a blue sub-pixel area, the third color filter CF3 may include a blue color filter material.

The black matrix BM may be arranged between or at the boundaries of the first to third sub-pixel areas SPA1, SPA2, and SPA3 (or the first to third sub-pixels SPX1, SPX2, and SPX3 of FIG. 1) and may include an opening which overlaps with each of the first to third sub-pixel areas SPA1, SPA2, and SPA3. For example, the black matrix BM may be arranged between the first color filter CF1, the second color filter CF2, and the third color filter CF3, respectively, and may include openings where the color filters CF may be arranged.

The black matrix BM may define first to third sub-pixel areas SPA1, SPA2, and SPA3 and a non-emission area NEA. The first to third sub-pixel areas SPA1, SPA2, and SPA3 may be areas corresponding to the openings in the black matrix BM, and the non-emission area NEA may be an area corresponding to the black matrix BM.

The black matrix BM may include at least one light-shielding and reflective material. The black matrix BM may include an organic material such as an acrylic resin, an epoxy resin, a phenol resin, a polyamide resin, a polyimide resin, a polyester resin, a polyphenylene sulfide resin, or a benzocyclobutene (BCB). However, the black matrix BM is not necessarily limited thereto, and may include various types of inorganic materials including a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), or a titanium oxide (TiOx).

The black matrix BM may protrude further in the opposite direction of the third direction DR3 than the color filters CF, or may be arranged in combination with a spacer such that a gap between the color filter layer CFL and the encapsulation layer TFE is formed (e.g., such that the black matrix BM is spaced apart from and not in contact with the first electrochromic element electrode ECE.

In FIG. 12, embodiments in which the black matrix BM is arranged between the color filters CF are shown, but embodiments according to the present disclosure are not limited thereto. According to some embodiments, the black matrix BM may be omitted. In this case, in a portion of the display device DD (e.g., a region overlapping with the non-emission area NEA), the first color filter CF1, the second color filter CF2, and the third color filter CF3 may be stacked to overlap. In this case, the non-emission area NEA may be defined as the area where the first color filter CF1, the second color filter CF2, and the third color filter CF3 overlap.

The second circuit layer PCL2 may be arranged on the color filter layer CFL. The second circuit layer PCL2 may include a substrate forming a base of the second circuit layer PCL2, and conductive layers and insulating layers arranged on the substrate. The conductive layers arranged on the substrate may form the first electrochromic element circuit electrically connected to the first electrochromic element ECD1, the second electrochromic element circuit electrically connected to the second electrochromic element ECD2, and the third electrochromic element circuit electrically connected to the third electrochromic element ECD3.

According to some embodiments, the second circuit layer PCL2 may include sensing electrodes for forming a touch sensor layer. The touch sensor layer might not be arranged between the encapsulation layer TFE and the electrochromic element ECD, but may be arranged within the second circuit layer PCL2.

Although not shown in FIG. 12, in the peripheral area PA, the second circuit layer PCL2 may be electrically connected to the first circuit layer PCL1 via a contact hole penetrating configurations arranged under the second circuit layer PCL2. The electrochromic element ECD may be electrically connected to the second circuit layer PCL2, and to the first circuit layer PCL1 and the second circuit layer PCL2 via a contact hole and may receive a synchronization signal for the pixel PXL.

Hereinafter, with reference to FIG. 13, further details of the display panel DP2 illustrated and described with respect to FIG. 6 will be described. Hereinafter, some repetitive descriptions that are already mentioned above may be omitted.

Referring to FIGS. 1, 6 and 13, according to some embodiments, the second circuit layer PCL2 may be arranged between the electrochromic element ECD and the color filter layer CFL. The second circuit layer PCL2 may be arranged on the electrochromic element ECD, and the color filter layer CFL may be arranged on the second circuit layer PCL2.

According to some embodiments, a spacer may be further arranged between the second circuit layer PCL2 and the first electrochromic element electrode ECE to form a gap between the second circuit layer PCL2 and the first electrochromic element electrode ECE.

The black matrix BM may protrude farther in the third direction DR3 than the color filters CF. In some embodiments, the black matrix BM may be omitted.

The protective layer OC may be further arranged on the color filter layer CFL. The protective layer OC may protect the color filter layer CFL in a process of forming the color filter layer CFL on the second circuit layer PCL2 and then flipping the second circuit layer PCL2 to form the electrochromic element ECD on the second circuit layer PCL2.

Hereinafter, with reference to FIG. 14, further details of the display panel DP3 as illustrated and described with respect to FIG. 7 will be described. Some repetitive descriptions that are already mentioned above may be omitted.

Referring to FIGS. 1, 7 and 14, according to some embodiments, the second circuit layer PCL2 may be arranged under the electrochromic element ECD. The second circuit layer PCL2 may be arranged between the electrochromic element ECD and the display element layer DPL. The second circuit layer PCL2 may be arranged above the encapsulation layer TFE layer, and the electrochromic element ECD may be arranged on the second circuit layer PCL2.

The adhesive layer PSL may be arranged between the display element layer DPL (or the encapsulation layer TFE) and the electrochromic element ECD. The substrate of the second circuit layer PCL2 may be attached to the encapsulation layer TFE via the adhesive layer PSL.

According to some embodiments, the second electrochromic element electrode EAE may be arranged under the first electrochromic element electrode ECE. For example, the second electrochromic element electrode EAE may be arranged on the second circuit layer PCL2, the electrochromic layer ECL may be arranged on the second electrochromic element electrode EAE, and the first electrochromic element electrode ECE may be arranged on the electrochromic layer ECL.

According to some embodiments, the touch sensor layer TSL may be further arranged on the color filter layer CFL.

Hereinafter, with reference to FIG. 15, further details of the display panel DP4 as illustrated and described with respect to FIG. 8 will be described. Some repetitive descriptions that are already mentioned above may be omitted.

Referring to FIGS. 1, 8, and 15, according to some embodiments, the encapsulation layer TFE on the display element layer DPL may be omitted. According to some embodiments, the filling layer FL may be arranged on the display element layer DPL. The filling layer FL may be arranged between the display element layer DPL and the second circuit layer PCL2.

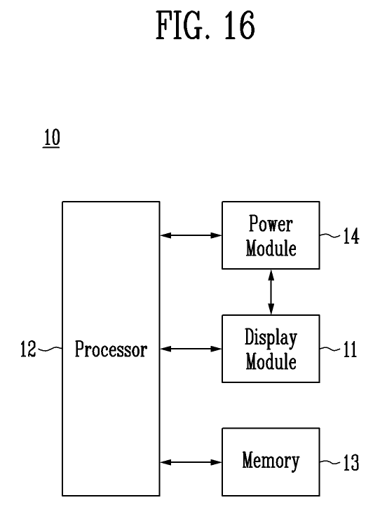

FIG. 16 is a block diagram of an electronic device 10 according to some embodiments. Referring to FIG. 16, the electronic device 10 according to some embodiments may include a display module 11, a processor 12, memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data information necessary for an operation of the processor 12 or the display module 11. When the processor 12 executes an application stored in the memory 13, an image data signal and/or an input control signal are transmitted to the display module 11, and the display module 11 may process the received signal and output image information through a display screen.

The power module 14 may include a power supply module such as a power adapter or a battery device, and a power conversion module which converts power supplied by the power supply module to generate power necessary for an operation of the electronic device 10.

At least one of the respective components of the electronic device 10 may be included in the display device DD according to the above-described embodiments. In addition, one or more of individual modules which are functionally included in one module may be included in the display device DD, and individual modules other than the one or more of the individual modules may be provided separately from the display device DD. For example, the display device DD may include the display module 11, and the processor 12, the memory 13, and the power module 14 may be provided in the form of other devices in the electronic device 10 other than the display device DD.

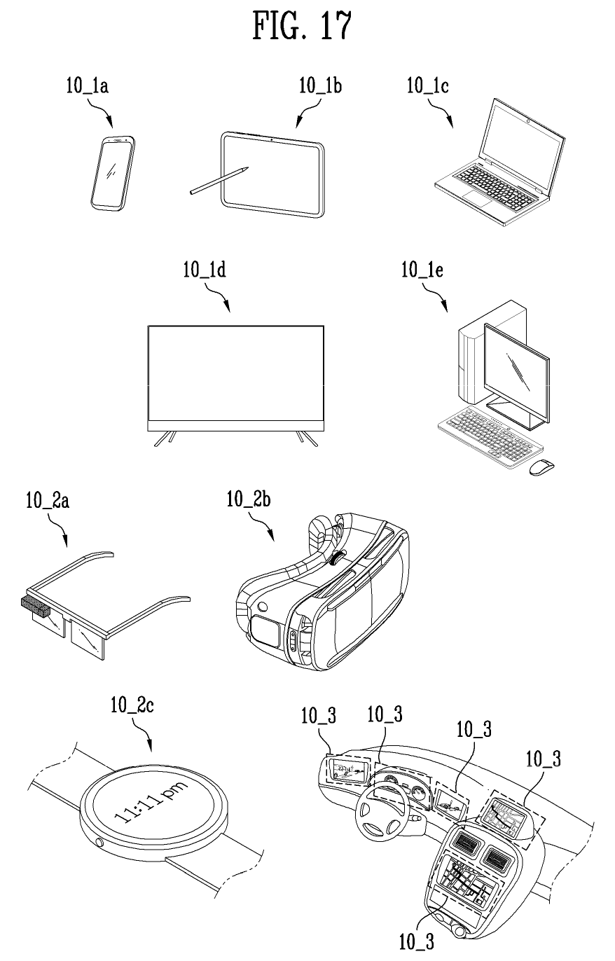

FIG. 17 includes schematic diagrams of an electronic device according to various embodiments.

Referring to FIG. 17, examples of various electronic devices, to which the display device according to some embodiments is applied, may include an electronic device for displaying images, such as a smartphone 10_1a, a tablet PC 10_1b, a laptop 10_1c, a television 10_1d, or a desk monitor 10_1e, as well as a wearable electronic device including a display module, such as smart glasses 10_2a, a head-mounted display 10_2b, or a smart watch 10_2c, and an automotive electronic device 10_3 including a display module, such as an automotive dashboard, a center fascia, a Center Information Display (CID) placed on a dashboard, or a room mirror display.

Aspects of some embodiments of the present disclosure have been described above with reference to aspects of some embodiments, but those skilled in the art or those having ordinary skill in the art will understand that various modifications and changes to the present disclosure can be made without departing from the spirit and technical scope of the present disclosure as set forth in the appended claims.

Accordingly, the characteristics of embodiments according to the present disclosure should not be limited to the descriptions mentioned in the detailed description of the specification, but should be determined by the appended claims, and their equivalents.

According to some embodiments of the present disclosure, a display device capable of switching from a self-emissive display device to a reflective display device or from a reflective display device to a self-emissive display device may be provided.

According to some embodiments of the present disclosure, an electronic device including the display device may be provided.

However, the effects of the present disclosure are not limited to the effects described above, and may be variously extended without departing from the spirit and scope of the present disclosure.

What is claimed is:

1. A display device, comprising:
a first circuit layer;
a display element layer on the first circuit layer;
an electrochromic element on the display element layer;
a second circuit layer electrically connected to the electrochromic element; and
a color filter layer on the electrochromic element,
wherein the display element layer comprises a first light emitting element and a second light emitting element,
wherein the electrochromic element comprises a first electrochromic element overlapping with the first light emitting element and a second electrochromic element overlapping with the second light emitting element, and
wherein the first electrochromic element and the second electrochromic element are configured to be driven individually.

2. The display device according to claim 1, wherein the second circuit layer is arranged on the color filter layer.

3. The display device according to claim 1, further comprising a protective layer on the color filter layer,
wherein the second circuit layer is between the color filter layer and the electrochromic element.

4. The display device according to claim 3, wherein the protective layer is an overcoat layer or a film layer.

5. The display device according to claim 1, wherein the second circuit layer is between the display element layer and the electrochromic element.

6. The display device according to claim 5, further comprising a touch sensor layer on the color filter layer.

7. The display device according to claim 6, further comprising an adhesive layer between the display element layer and the electrochromic element.

8. The display device according to claim 6, further comprising a filling layer between the display element layer and the second circuit layer.

9. The display device according to claim 8, wherein the filling layer includes a vacuum or comprises a filler.

10. The display device according to claim 1, further comprising:
an encapsulation layer on the display element layer; and
a touch sensor layer between the encapsulation layer and the electrochromic element.

11. The display device according to claim 1, wherein the color filter layer comprises:
a first color filter;
a second color filter; and
a black matrix between the first color filter and the second color filter.

12. The display device according to claim 11, wherein the electrochromic element comprises:
a first electrochromic element electrode;
an electrochromic layer on the first electrochromic element electrode; and
a second electrochromic element electrode on the electrochromic layer, and
wherein the black matrix is spaced apart from the first electrochromic element electrode.

13. The display device according to claim 11, wherein the electrochromic element comprises:
a first electrochromic element electrode;
an electrochromic layer on the first electrochromic element electrode; and
a second electrochromic element electrode on the electrochromic layer, and
wherein the display device further comprises a transparent inorganic layer between the second electrochromic element electrode and the color filter layer.

14. The display device according to claim 1, wherein the color filter layer comprises:
a first color filter;
a second color filter; and
a third color filter, and
wherein, in a portion of the display device, the first color filter, the second color filter, and the third color filter overlap with each other.

15. The display device according to claim 1, further comprising:
a display area and a non-display area,
wherein the electrochromic element is electrically connected to the first circuit layer via a contact hole arranged in the non-display area.

16. An electronic device, comprising:
a display device and a processor,
wherein the display device comprises:
a first circuit layer;
a display element layer on the first circuit layer;
an electrochromic element on the display element layer;
a second circuit layer electrically connected to the electrochromic element, and comprising a first electrochromic element circuit and a second electrochromic element circuit; and
a color filter layer on the electrochromic element,
wherein the electrochromic element comprises a first electrochromic element and a second electrochromic element,
wherein the first electrochromic element is electrically connected to the first electrochromic element circuit, and
wherein the second electrochromic element is electrically connected to the second electrochromic element circuit.

17. The electronic device according to claim 16, wherein the second circuit layer is arranged on the color filter layer.

18. The electronic device according to claim 16, further comprising a protective layer on the color filter layer,
wherein the second circuit layer is between the color filter layer and the electrochromic element, and
wherein the protective layer is an overcoat layer or a film layer.

19. The electronic device according to claim 16, further comprising:
a touch sensor layer on the color filter layer; and
an adhesive layer between the display element layer and the electrochromic element,
wherein the second circuit layer is between the display element layer and the electrochromic element.

20. The electronic device according to claim 16, further comprising:
a touch sensor layer on the color filter layer; and
a filling layer between the display element layer and the second circuit layer,
wherein the second circuit layer is between the display element layer and the electrochromic element.
